(19) United States
(12) Patent Application Publication
(10) Pub. No.: US 2004/0135707 A1
(43) Pub. Date: Jul. 15, 2004

(54) Electronic device and push button thereof

(76) Inventor: Shen Chang Tsao, Taoyuan (TW)

Correspondence Address: BIRCH STEWART KOLASCH & BIRCH, PO BOX 747, FALLS CHURCH, VA, 22040-0747, US

(21) Appl. No.: 10/341,401

(22) Filed: Jan. 14, 2003

(51) Int. Cl. H03M 11/00; H03K 17/94

(52) U.S. Cl. 341/22

(57) ABSTRACT

An electronic device includes a main case body, a push button, and a control circuit board. In this case, the push button is set on the main case body and includes a button main body and at least a fixed side wing. A set of button convex portions are formed on a surface of the button main body, and a support convex portion is formed in the middle of the button main body corresponding to each button convex portion. The fixed side wing extends from a side of the button main body, and one side of the fixed side wing is attached to the main case body. The control circuit board, which is form on the main case body, has a surface for providing a set of touching switches. Each of the touching switches is provided corresponding to each of the button convex portions, and the support convex portion of the push button is contact with the control circuit board. Furthermore, the invention also discloses a push button for the electronic device.

### BACKGROUND OF THE INVENTION

1. Field of Invention

The invention relates to an electronic device and a push button thereof and, in particular, to an electronic device and a push button used in notebook computers, keyboards, and the like.

2. Related Art

As the advancements of electronic devices, manufacturers always work hard for making their electronic products perfect and more economic. Therefore, these electronic products may have better competitiveness.

Generally speaking, the so-called electronic device could be a mouse, a controller, a notebook computer, or a keyboard. In the mentioned electronic device, operating buttons and relative components are usually provided.

Referring to FIG. 1, a conventional notebook computer 1 includes a set of buttons 10, a case main body (upper case) 11, and a control circuit board (not shown). The set of buttons 10 include a moving button 100, a rotation button 101, and a specific button 102. Please referring to FIGS. 2 and 3, the rotation button 101 includes a button main body 101a and a pivoting housing 101b. A pair of button convex portions 101c is formed on one surface of the button main body 101a. The pivoting housing 101b is pivoted on a shaft (not shown) of the case main body 11, so that the pivoting housing 101b can be tilted in two directions to touch the touching switches of the control circuit board. As a result, the operations that the user desires can be executed.

However, in the mentioned structure of buttons, since the surface of the rotation button 101 may be coated with lacquer, the pivoting housing 101b may be attached with the shaft of the main case body 11. Therefore, the pivoting housing 101b may be stuck and malfunction. Moreover, the rotation button 101 is pivoted on the main case body 11 through the pivoting housing 101b and the shaft, so that the rotation button 101 may slide horizontally. As a result, the rotation button 101 may be abnormal, and, more particularly, the rotation button 101 may be tilted.

Therefore, it is an important subject of the invention to improve the quality of electronic devices, and to posit the rotation button of electronic device to avoid tilting and being stuck.

### SUMMARY OF THE INVENTION

In view of the above-mentioned problems, an objective of the invention is to provide a push button having good controlling quality and an electronic device having the push button.

The invention is characterized in utilizing a push button having a support convex portion and a fixed side wing. Therefore, the push button is supported with the support convex portion, so that the push button may not be stuck while operation. Furthermore, a button main body of the push button has one side extended with the fixed side wing, so that the push button would not slide and be tilted after operation.

To achieve the above-mentioned objective, the invention provides a push button for an electronic device including a button main body and at least a fixed side wing. The button main body has a surface formed with a set of button convex portions and a support convex portion. The support convex portion is formed in the middle of the button main body relating to each of the button convex portions. The fixed side wing extends from one side of the button main body.

Furthermore, this invention also discloses an electronic device including a main case body, a push button, and a control circuit board. In this invention, the push button is set on the main case body and has a button main body and at least a fixed side wing. The button main body has a set of button convex portions and a support convex portion. The button convex portions are formed on one surface of the button main body, and the support convex portion is formed in the middle of the button main body relating to each of the button convex portions. The fixed side wing extends from one side of the button main body and has an end attached to the main case body. The control circuit board is provided on the main case body and has a set of touching switches formed on a surface of that. Each of the touching switches is provided corresponding to each of the button convex portions, and the support convex portion is contact with the control circuit board.

As mentioned above, the push button would not be stuck while operation, and the push button would not be tilted after operation.

### BRIEF DESCRIPTION OF THE DRAWINGS

The invention will become more fully understood from the detailed description given herein below illustration only, and thus are not limitative of the present invention, and wherein:

FIG. 1 is a schematic illustration showing the conventional electronic device;

FIG. 2 is a schematic illustration showing the rotation button of the conventional electronic device;

FIG. 3 is a schematic illustration showing a side view and a bottom view of the rotation button of the conventional electronic device;

FIG. 4 is a schematic illustration showing an electronic device according to a preferred embodiment of the invention;

FIG. 5 is a schematic illustration showing a push button according to a preferred embodiment of the invention;

FIG. 6 is a schematic illustration showing a side view and a bottom view of a push button according to a preferred embodiment of the invention; and

FIG. 7 is a partial schematic illustration showing the push button attached on the main case body.

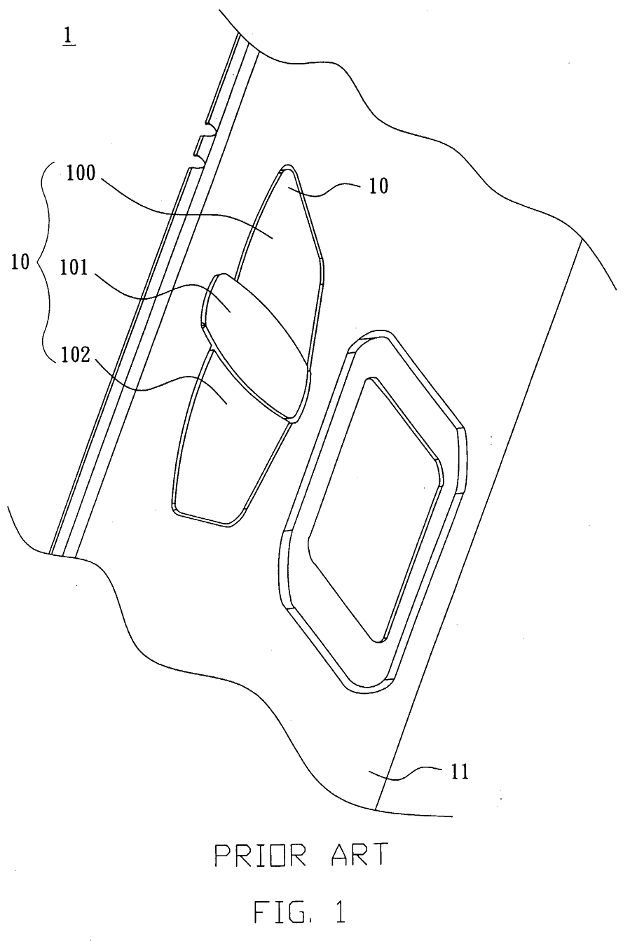

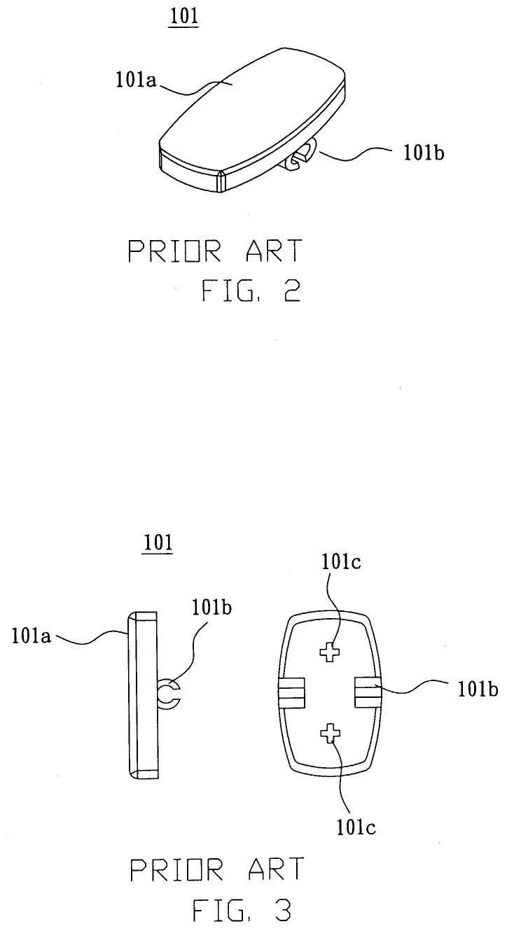

### DETAILED DESCRIPTION OF THE INVENTION

An electronic device and a push button of the electronic device according to the preferred embodiment of the invention will be described herein below with reference to the accompany drawings, wherein the same reference numbers refer to the same elements.

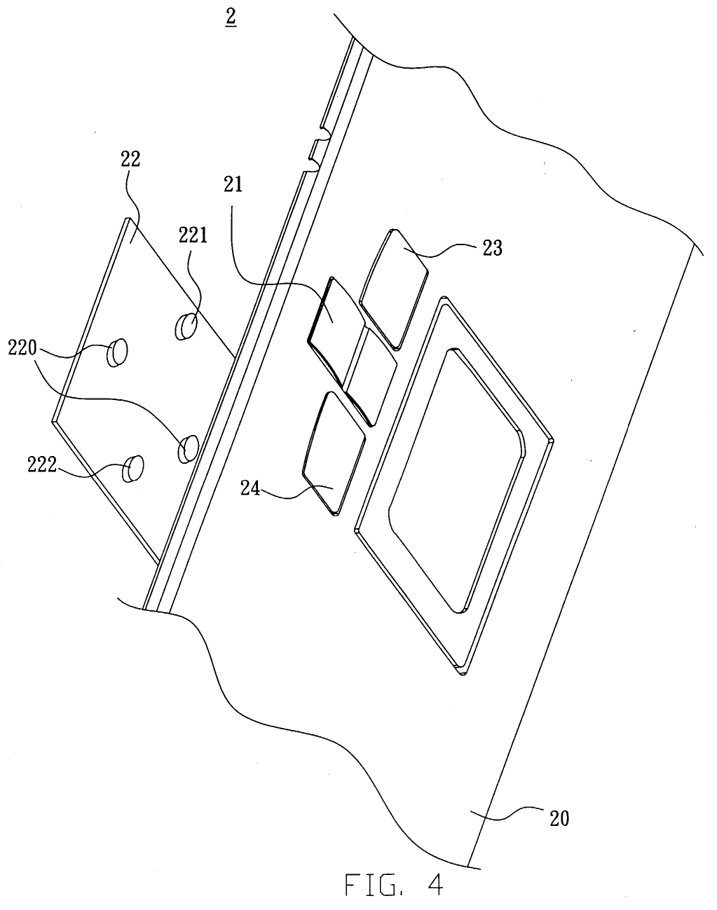

Please refer to FIG. 4, the electronic device 2 according to a preferred embodiment of the invention includes a main case body 20, a push button 21, and a control circuit board 22.

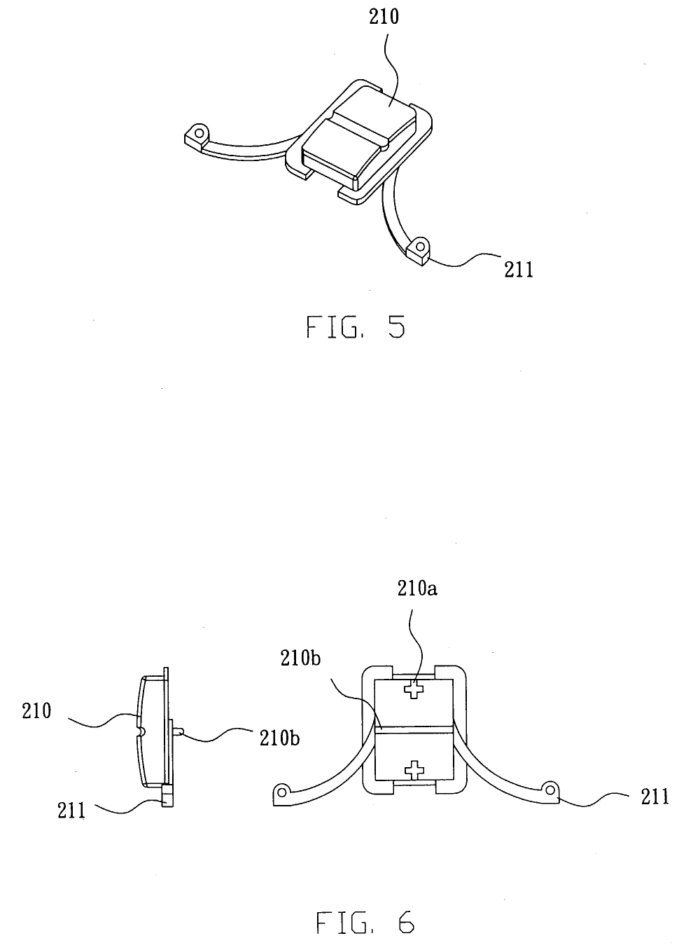

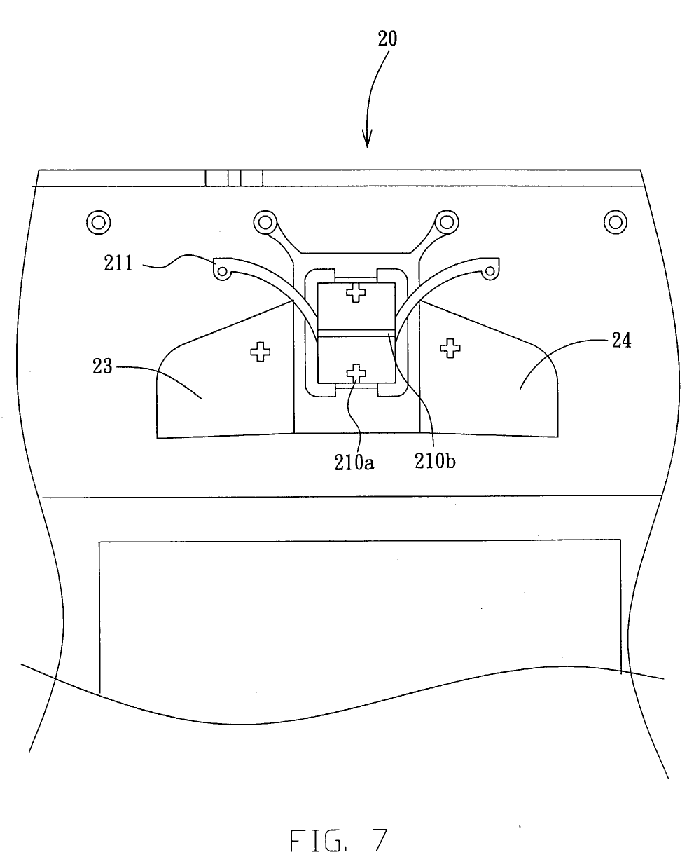

As shown in FIGS. 5 and 6, the push button 21 includes a button main body 210 and at least one fixed side wing 211. In the current embodiment, the push button 21 has two fixed side wings 211. With reference to FIG. 7, the push button 21 is attached on the main case body 20 by utilizing the fixed side wings 211. A set of button convex portions 210a and a support convex portion 210b are provided on a surface of the button main body 210 of the push button 21. The support convex portion 210b is formed in the middle of the button main body 210 relating to each of the button convex portions 210a. The fixed side wings 211 respectively extend from two opposition sides of the button main body 210, and one end of each of the fixed side wings 211 is mounted on the main case body 20. In this case, the main case body 20 is an upper case of a notebook computer, and the push button 21 is a rotation button of a notebook computer.

In addition, a moving button 23 and a specific button 24 can be provided adjacent to the push button 21. Moreover, the fixed side wings 211 can be attached on the main case body 20 by welding.

Furthermore, a set of first touching switches 220 is formed on one surface of the control circuit board 22. In this case, the mentioned support convex portions 210b are contact with the control circuit board 22 and located in the middle of the first touching switches 220. Therefore, each of the first touching switches 220 is provided corresponding to each button convex portion 210a of the push button 21. Hence, while the support convex portion 210b is against the control circuit board 22, the push button 21 is moved like a seesaw. Thus, when the push button 21 is pressed, one of the button convex portions 210a are contact with one of the first touching switches 220, respectively. In addition, in this embodiment, the control circuit board 22 can further have a second touching switch 221 and a third touching switch 222. The second touching switch 221 is provided opposite to the moving button 23 while the third touching switch 222 is provided opposite to the specific button 24.

In addition, the present invention also discloses a push button of an electronic device. In this case, the push button of this invention is equal to the mentioned push button 21 shown in FIG. 4.

To sum up, the electronic device and push button according to the embodiments of the invention can prevent fluctuation and unfixed of the push button, and the push button would not be stuck while operation. Therefore, the quality of push button can be greatly improved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A push button, comprising:
a button main body having a surface formed with a set of button convex portions and a support convex portion, the support convex portion being formed in the middle of the button main body relating to each of the button convex portions; and
at least a fixed side wing extending from a side of the button main body.

2. The push button of claim 1, which is a rotation button of a notebook computer.

3. The push button of claim 1, which comprises two fixed side wings, the fixed side wings respectively extending from two opposition sides of the button main body.

4. An electronic device, comprising:
a main case body;
a push button, which is set on the main case body and has a button main body and at least a fixed side wing, the button main body having a set of button convex portions formed on a surface of the button main body and a support convex portion formed in the middle of the button main body relating to each of the button convex portions, the fixed side wing extending from a side of the button main body and having one side attached to the main case body; and
a control circuit board, which is provided on the main case body and has a set of touching switches formed on a surface of the control circuit board, each of the touching switches being provided corresponding to each of the button convex portions and the support convex portion being contact with the control circuit board.

5. The electronic device of claim 4, wherein the push button comprises two fixed side wings, and the fixed side wings respectively extends from two opposition sides of the button main body.

6. The electronic device of claim 4, wherein the main case body is an upper case of a notebook computer.

7. The electronic device of claim 4, wherein the push button is a rotation button of a notebook computer.
